(19) United States
(12) Patent Application Publication
(10) Pub. No.: US 2026/0371901 A1
(43) Pub. Date: Nov. 19, 2026

(54) DISPLAY DEVICE AND ELECTRONIC DEVICE

(71) Applicant: Samsung Display Co., LTD., Yongin-si (KR)

(72) Inventors: JOOHYEON LEE, Yongin-si (KR); SEUNG-WON KUK, Yongin-si (KR); Hyunseok Oh, Yongin-si (KR); HYUNKYUNG YUN, Yongin-si (KR)

(21) Appl. No.: 19/642,140

(22) Filed: Apr. 8, 2026

(30) Foreign Application Priority Data
May 14, 2025 (KR) 10-2025-0062560

(51) Int. Cl. H10K 59/80; H10K 102/00

(52) U.S. Cl. CPC H10K 59/873; H10K 2102/311

(57) ABSTRACT

A display device includes a display panel, on which a display element is arranged, where the display panel includes a folding area along which a folding axis is defined, and a non-folding area adjacent to the folding area, a resin layer arranged on the display panel, and a cover window arranged on the resin layer, where the cover window includes glass, the resin layer includes a convex portion which is convex toward the cover window, the cover window includes a concave portion corresponding to the convex portion of the resin layer, and the convex portion and the concave portion overlap each other, the resin layer includes a first resin layer arranged adjacent to the display panel and a second resin layer arranged adjacent to the cover window, and a first elastic modulus of the first resin layer is greater than a second elastic modulus of the second resin layer.

This application claims priority to Korean Patent Application No. 10-2025-0062560, filed on May 14, 2025, and all the benefits accruing therefrom under 35 U.S.C. § 119, the content of which in its entirety is herein incorporated by reference.

### BACKGROUND

### 1. Field

The disclosure relates to a display device and an electronic device.

### 2. Description of the Related Art

Display devices provide information to users by displaying various images on display screens. A display device generally displays information within an allocated screen. Recently, flexible display devices including flexible display panels that are foldable or bendable have been developed. Flexible display devices, unlike rigid display devices, are foldable, rollable, or bendable. Flexible display devices having variously changeable shapes may be carried around without being restricted by the existing screen size, thereby improving user convenience.

The display device typically includes a display panel on which display elements are arranged and a cover window for protecting lower structures on the display r.

### SUMMARY

A display device may include a resin layer for bonding a display panel and a cover window to each other. The resin layer included in the display device is desired to maintain reliability even after repeated folding or bending, and to have high impact resistance.

Embodiments of the disclosure provide a display device capable of maintaining reliability even after folding or bending and an electronic device including the display device.

Embodiments of the disclosure also provide a display device having sufficiently or desirably high impact resistance and an electronic device including the display device.

According to an embodiment of the disclosure, a display device includes a display panel, in which a display element is arranged, where the display panel includes a folding area along which a folding axis is defined, and a non-folding area adjacent to the folding area, a resin layer arranged on the display panel, and a cover window arranged on the resin layer, where the cover window includes glass, the resin layer includes a convex portion which is convex toward the cover window, the cover window includes a concave portion corresponding to the convex portion of the resin layer, and the convex portion and the concave portion overlap each other, the resin layer includes a first resin layer arranged adjacent to the display panel and a second resin layer arranged adjacent to the cover window, and a first elastic modulus of the first resin layer is greater than a second elastic modulus of the second resin layer.

In some embodiments, an elastic modulus of the entire resin layer may be in a range from about 40 megapascals (MPa) to about 100 MPa.

In some embodiments, an adhesion of the resin layer may be about 1000 gram-force (g·f) or greater.

In some embodiments, the first elastic modulus may be in a range from about 10 MPa to about 1000 MPa.

In some embodiments, the second elastic modulus may be in a range from about 0.01 MPa to about 0.1 MPa.

In some embodiments, a ratio of a thickness of the second resin layer to a thickness of the first resin layer is in a range from about 0.5:1 to about 1:1.

According to another embodiment of the disclosure, an electronic device includes a processor which generates a scan input signal, a power module which generates a scan input voltage, and a display device which processes the scan input signal and displays an image, where the display device includes a display panel in which a display element is arranged, where the display panel includes a folding area along which a folding axis is defined, and a non-folding area adjacent to the folding area, a resin layer arranged on the display panel, and a cover window arranged on the resin layer, where the cover window includes glass, the resin layer includes a convex portion which is convex toward the cover window, the cover window includes a concave portion corresponding to the convex portion of the resin layer, and the convex portion and the concave portion overlap each other, the resin layer includes a first resin layer arranged adjacent to the display panel and a second resin layer arranged adjacent to the cover window, and a first elastic modulus of the first resin layer is greater than a second elastic modulus of the second resin layer.

In some embodiments, an elastic modulus of the entire resin layer may be in a range from about 40 MPa to about 100 MPa.

In some embodiments, an adhesion of the resin layer may be about 1000 g·f or greater.

In some embodiments, the first elastic modulus may be in a range from about 10 MPa to about 1000 MPa.

In some embodiments, the second elastic modulus may be in a range from about 0.01 MPa to about 0.1 MPa.

In some embodiments, a ratio of a thickness of the second resin layer to a thickness of the first resin layer is in a range from about 0.5:1 to about 1:1.

### BRIEF DESCRIPTION OF THE DRAWINGS

FIG. 1 is a view schematically showing a display device according to an embodiment of the disclosure;

FIG. 2 is a perspective view showing the display device of FIG. 1 in a folded state;

FIG. 3 is a cross-sectional view taken along line I-I′ of FIG. 1 schematically showing an embodiment of a display panel;

FIG. 4 is a cross-sectional view schematically showing a stacked structure of a display device according to an embodiment of the disclosure;

FIG. 5 is a cross-sectional view schematically showing a stacked structure of a display device according to another embodiment of the disclosure;

FIG. 6 is a cross-sectional view showing the stacked structure of the display device of FIG. 5 in a folded state;

FIGS. 7A to 7E are photographs showing folding characteristics of a comparative example of the disclosure;

FIG. 8 is a graph showing measured impact resistance characteristics of an embodiment and a comparative example of the disclosure;

FIG. 9 is a block diagram of an electronic device including a display device according to an embodiment of the disclosure; and

FIG. 10 schematically shows an electronic device including a display device according to various embodiments of the disclosure.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the following embodiments, when a portion, such as a film, a region, a component, etc., is present on or above another portion, this case may include not only a case where it is directly on the other portion, but also a case where another film, region, component, etc., is arranged between the portion and the other portion.

In the following embodiments, terms such as connect or combine do not necessarily imply a direct and/or fixed connection or combination of two members, unless the context clearly indicates otherwise, and do not exclude the presence of another member between the two members.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In the drawings, the size of components may be exaggerated or reduced for convenience of description. For example, as the size and thickness of each component shown in the drawings are arbitrarily shown for convenience of description, the disclosure is not necessarily limited to the illustration.

Hereinafter, embodiments of the disclosure will be described in detail with reference to the attached drawings, and in the description with reference to the drawings, identical or corresponding components are given the same reference numerals and any repetitive detailed descriptions thereof will be omitted or simplified.

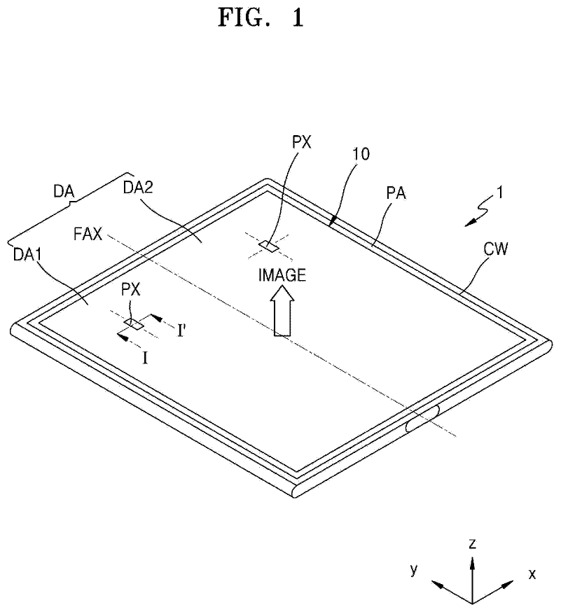

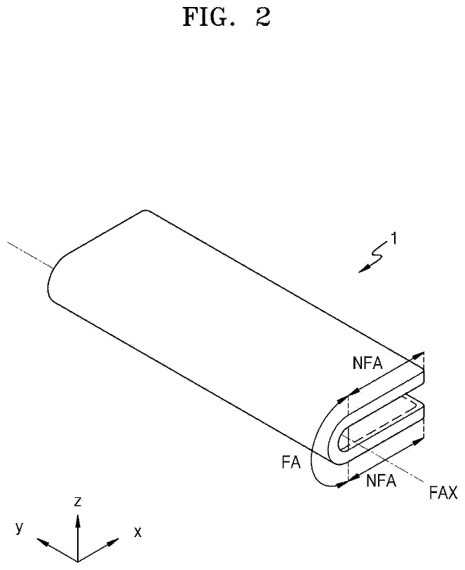

FIG. 1 is a view schematically showing a display device according to an embodiment of the disclosure, and FIG. 2 is a perspective view showing the display device of FIG. 1 in a folded state.

Referring to FIGS. 1 and 2, an embodiment of a display device 1 may display a moving image or a still image, and may be used as a display screen for various products such as not only portable electronic devices including mobile phones, smart phones, tablet personal computers (PCs), mobile communication terminals, electronic notebooks, electronic books, portable multimedia players (PMPs), navigation devices, ultra mobile PCs (UMPCs), etc., but also televisions (TVs), laptop computers, monitors, billboards, Internet of things (IOT) devices, etc.

The display device 1 according to an embodiment may be used in wearable devices such as smart watches, watch phones, glasses-type displays, and head mounted displays (HMDs). The display device 1 according to an embodiment may also be used as a dashboard of a vehicle and a center information display (CID) placed on a center fascia or dashboard of a vehicle, a room mirror display replacing a side mirror of a vehicle, or a display screen placed on the back of a front seat as entertainment for a rear seat of a vehicle.

The display device 1 may have a roughly rectangular shape when viewed in the z direction or the −z direction as shown in FIG. 1. Here, the z direction or the −z direction may be a thickness direction of the display device 1. For example, the display device 1 may have an overall rectangular planar shape having a short side extending in a first direction (e.g., an x direction or a −x direction) and a long side extending in a second direction (e.g., a y direction or a −y direction), as shown in FIG. 1. In an embodiment, a portion where the short side extending in the first direction (e.g., the x direction or the −x direction) and the long side extending in the second direction (e.g., the y direction or the −y direction) meet each other may have a right-angled shape or a round shape with a selected curvature. The planar shape (i.e., a shape when viewed in the z direction or the −z direction) of the display device 1 is not limited to a rectangle, and may have other polygonal shapes, a circular shape, or an elliptical shape.

In an embodiment, the display device 1 may include a display panel 10 and a cover window CW.

The display device 1 may include non-folding areas NFA and a folding area FA arranged therebetween. The non-folding areas NFA and the folding area FA may be arranged in the first direction (the x direction). The display device 1 may be folded as the folding area FA is bent around a folding axis FAX parallel to the second direction (the y direction).

The display panel 10 may include a display area DA and a peripheral area PA. The display area DA may display images. Pixels PX may be arranged in the display area DA. The display panel 10 may provide an image using light emitted from the pixels PX. Each pixel PX may emit light using a display element DE. In an embodiment, each pixel PX may emit red, green, or blue light. In an embodiment, each pixel PX may emit red, green, blue, or white light.

The peripheral area PA may be a non-display area that does not provide an image. The peripheral area PA may at least partially surround the display area DA. In an embodiment, for example, the peripheral area PA may entirely surround the display area DA. In the peripheral area PA, driving units that provide electrical signals to the pixels PX, a power line for providing power, etc., may be arranged. In an embodiment, for example, a scan driving unit for applying a scan signal to the pixels PX may be arranged in the peripheral area PA. A data driving unit for applying a data signal to the pixels PX may be arranged in the peripheral area PA.

The display area DA may include a first display area DA1 and a second display area DA2 arranged on opposite sides with respect to a line where the display area DA meets a plane extending in the z direction of the folding axis FAX defined by the folding area FA. The display panel 10 may provide a first image and a second image using light emitted from a plurality of pixels PX arranged in the first display area DA1 and the second display area DA2. In an embodiment, the first image and the second image may be parts of any one image provided through the display area DA of the display panel 10. In another embodiment, the display panel 10 may provide the first and second images that are independent of each other.

The display panel 10 may be folded around the folding axis FAX. In an embodiment, the display panel 10 may be a foldable display panel. In an embodiment, in a state where the display panel 10 is folded, the first display area DA1 and the second display area DA2 of the display panel 10 may face each other. In another embodiment, in a state where the display panel 10 is folded, the first display area DA1 and the second display area DA2 of the display panel 10 may face opposite directions.

That is, in an embodiment, the display panel 10 may be in-folded or out-folded with respect to the folding axis FAX. Herein, in-folding may mean that the display panel 10 is folded in the +z direction with respect to the folding axis FAX, and out-folding may mean that the display panel 10 is folded in the −z direction with respect to the folding axis FAX. In other words, in-folding may mean that a top surface of the cover windows CW arranged on the display panel 10 is folded such that folded top surfaces face each other, and out-folding may mean that a bottom surface of the cover windows CW is folded such that folded bottom surfaces face each other.

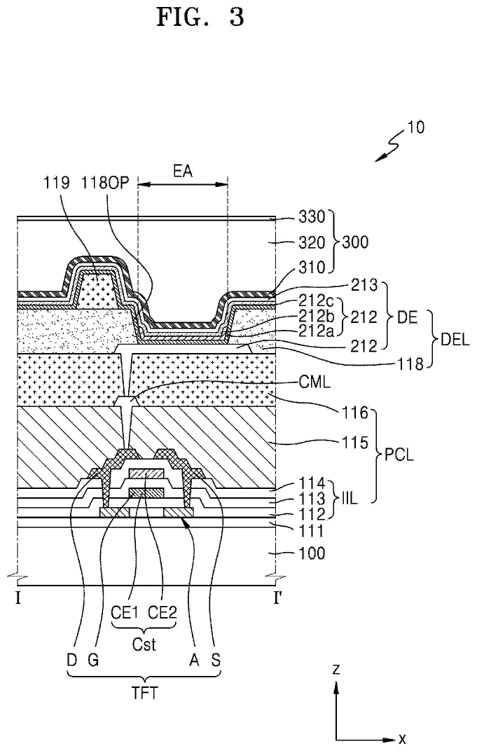

The bottom surface of the cover window CW may mean a surface that is closer to a substrate 100 (see FIG. 3) in the z direction than the top surface of the cover window CW. FIGS. 1 and 2 show an embodiment where the folding axis FAX extends in the second direction (the y direction) as an example, but the disclosure is not limited thereto.

In an embodiment, the folding axis FAX may extend in the first direction (the x direction) intersecting the second direction (the y direction). Alternatively, the folding axis FAX on an xy plane may extend in a direction intersecting the first direction (the x direction) and the second direction (the y direction). Although FIGS. 1 and 2 illustrate an embodiment where a single folding axis FAX is defined as an example, the disclosure is not limited thereto.

In an embodiment, the display panel 10 may be folded around two folding axes FAX that cross the display area DA. For example, in an embodiment where the display panel 10 is foldable with respect to two folding axes FAX, the display panel 10 may be in-folded with respect to one folding axis FAX and out-folded with respect to the remaining folding axis FAX.

In an embodiment, the display panel 10 may be in-folded or out-folded with respect to two folding axes FAX. In an embodiment, the display panel 10 may be folded with respect to a plurality of folding axes FAX that cross the display area DA. The display panel 10 may be in-folded or out-folded with respect to each folding axis FAX.

The cover window CW may be arranged on the display panel 10 and may cover the display panel 10. The cover window CW may be folded or bent by an external force without causing cracks, etc. When the display panel 10 is folded with respect to the folding axis FAX, the cover window CW may also be folded together and cover the display panel 10.

FIG. 3 is a cross-sectional view taken along line I-I′ of FIG. 1 schematically showing an embodiment of the display panel.

Referring to FIG. 3, an embodiment of the display panel 10 may include a substrate 100, a buffer layer 111, a pixel circuit layer PCL, a display element layer DEL, and an encapsulation layer 300. The substrate 100 may be glass or may include a polymer resin such as polyethersulfone, polyarylate, polyetherimide, polyethylene naphthalate, polyethylene terephthalate, polyphenylene sulfide, polyimide, polycarbonate, cellulose triacetate, cellulose acetate propionate, etc.

In an embodiment, the substrate 100 may have a multilayer structure including a base layer including polymer resin described above and a barrier layer (not shown). The substrate 100 including the polymer resin may have flexible, rollable, and bendable characteristics. The buffer layer 111 may be arranged on the substrate 100.

The buffer layer 111 may include an inorganic insulating material such as silicon nitride, silicon oxynitride, and silicon oxide, and may be a single layer or multilayer, each layer including at least one selected from the inorganic insulating materials listed above. The pixel circuit layer PCL may be arranged on the buffer layer 111.

The pixel circuit layer PCL may include an inorganic insulating layer IIL, a first planarization layer 115, and a second planarization layer 116, arranged on or/and under a thin film transistor TFT and components thereof. The inorganic insulating layer IIL may include a first gate insulating layer 112, a second gate insulating layer 113, and an interlayer insulating layer 114.

The thin film transistor TFT may include a semiconductor layer A that may include polysilicon. The semiconductor layer A may include at least one selected from amorphous silicon, an oxide semiconductor, an organic semiconductor, and the like. The semiconductor layer A may include a channel region and a drain region and a source region respectively arranged on opposite sides of the channel region. A gate electrode G may overlap the channel region.

The gate electrode G may include a low-resistance metal material. The gate electrode G may include a conductive material including molybdenum (Mo), aluminum (Al), copper (Cu), titanium (Ti), etc., and may be formed as a multilayer or single layer, each layer including at least one selected from the materials listed above.

The first gate insulating layer 112 between the semiconductor layer A and the gate electrode G may include an inorganic insulating material such as a silicon oxide (SiO₂), a silicon nitride (SiN_{X}), a silicon oxynitride (SiON), an aluminum oxide (Al₂O₃), a titanium oxide (TiO₂), a tantalum oxide (Ta₂O₅), a hafnium oxide (HfO₂), a zinc oxide (ZnO_{X}), etc. The zinc oxide (ZnO_{X}) may be a zinc oxide (ZnO) and/or a zinc peroxide (ZnO₂).

The second gate insulating layer 113 may be provided to cover the gate electrode G. Like the first gate insulating layer 112, the second gate insulating layer 113 may include an inorganic insulating material such as a silicon oxide (SiO₂), a silicon nitride (SiN_{X}), a silicon oxynitride (SiON), an aluminum oxide (Al₂O₃), a titanium oxide (TiO₂), a tantalum oxide (Ta₂O₅), a hafnium oxide (HfO₂), a zinc oxide (ZnO_{X}), etc. The zinc oxide (ZnO_{X}) may be a zinc oxide (ZnO) and/or a zinc peroxide (ZnO₂).

An upper electrode CE2 of the storage capacitor Cst may be arranged above the second gate insulating layer 113. The upper electrode CE2 may overlap the gate electrode G thereunder. The gate electrode G and the upper electrode CE2 overlapping each other with the second gate insulating layer 113 therebetween may form the storage capacitor Cst of the pixel circuit. The gate electrode G may function as a lower electrode CE1 of the storage capacitor Cst. In such an embodiment, the storage capacitor Cst and the thin film transistor TFT may be formed to overlap each other.

In some embodiments, the storage capacitor Cst may be formed not to overlap the thin film transistor TFT. The upper electrode CE2 may include aluminum (Al), platinum PT, palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the materials.

The interlayer insulating layer 114 may cover the upper electrode CE2. The interlayer insulating layer 114 may include a silicon oxide (SiO₂), a silicon nitride (SiN_{X}), a silicon oxynitride (SiON), an aluminum oxide (Al₂O₃), a titanium oxide (TiO₂), a tantalum oxide (Ta₂O₅), a hafnium oxide (HfO₂), a zinc oxide (ZnO_{X}), etc. The zinc oxide (ZnO_{X}) may be a zinc oxide (ZnO) and/or a zinc peroxide (ZnO₂).

The interlayer insulating layer 114 may be a single layer or multiple layers, each layer including at least one selected from the inorganic insulating materials listed above. Each of the drain electrode D and the source electrode S may be positioned on the interlayer insulating layer 114. The drain electrode D and source electrode S may include a material having good conductivity. The drain electrode D and the source electrode S may include a conductive material including molybdenum (Mo), aluminum (Al), copper (Cu), titanium (Ti), etc., and may be formed as multiple layers or a single layer, each layer including at least one selected from the materials listed above. In an embodiment, the drain electrode D and the source electrode S may have a multilayer structure of Ti/Al/Ti.

The first planarization layer 115 may be arranged to cover the drain electrode D and the source electrode S. The first planarization layer 115 may include an organic insulating layer. The first planarization layer 115 may include an organic insulator such as a general-purpose polymer like polymethylmethacrylate (PMMA) or polystyrene (PS), a polymer derivative having a phenol-based group, an acrylic polymer, an imide polymer, an aryl ether polymer, an amide polymer, a fluorinated polymer, a p-xylene polymer, a vinyl alcohol polymer, or a blend thereof.

In an embodiment, a connection electrode CML may be arranged above the first planarization layer 115.

In such an embodiment, the connection electrode CML may be connected to the drain electrode D or the source electrode S via a contact hole of the first planarization layer 115. The connection electrode CML may include a material with good conductivity. The connection electrode CML may include a conductive material including molybdenum (Mo), aluminum (Al), copper (Cu), titanium (Ti), etc., and may be formed as multiple layers or a single layer, each layer including at least one selected from the materials listed above. In an embodiment, the connection electrode CML may have a multilayer structure of Ti/Al/Ti.

The second planarization layer 116 may be arranged to cover the connection electrode CML. The second planarization layer 116 may include an organic insulating layer. The second planarization layer 116 may include an organic insulator such as a general-purpose polymer like polymethylmethacrylate (PMMA) or polystyrene (PS), a polymer derivative having a phenol-based group, an acrylic polymer, an imide polymer, an aryl ether polymer, an amide polymer, a fluorinated polymer, a p-xylene polymer, a vinyl alcohol polymer, or a blend thereof. The display element layer DEL may be arranged on the pixel circuit layer PCL.

The display element layer DEL may include a display element DE. The display element DE may be an organic light-emitting diode. A pixel electrode 211 of the display element DE may be electrically connected to the connection electrode CML through the contact hole of the second planarization layer 116.

The pixel electrode 211 may include a conductive oxide such as an indium tin oxide (ITO), an indium zinc oxide (IZO), a zinc oxide (ZnO), an indium oxide (In₂O₃), an indium gallium oxide (IGO), or an aluminum zinc oxide (AZO). In another embodiment, the pixel electrode 211 may include a reflective film including silver (Ag), magnesium (Mg), aluminum (Al), platinum PT, palladium (Pd), gold (Au), nickel (Ni), neodymium (Nd), iridium (Ir), chromium (Cr), or a compound thereof. In another embodiment, the pixel electrode 211 may further include a film including or formed of ITO, IZO, ZnO, or In₂O₃ on/under the reflective film.

A pixel-defining film 118 having an opening 1180P exposing a central portion of the pixel electrode 211 may be arranged on the pixel electrode 211. The pixel-defining film 118 may include an organic insulating material and/or an inorganic insulating material.

The opening 1180P may define an emission area EA of light emitted from the display element DE (hereinafter referred to as an emission area). A width of the opening 1180P may correspond to a width of the emission area EA of the display element DE. In an embodiment, the pixel-defining film 118 may include a light-blocking material and may be provided in black.

The light-blocking material may include a resin or paste containing carbon black, carbon nanotubes, and black dye, metal particles such as nickel, aluminum, molybdenum and alloys thereof, metal oxide particles (e.g., a chromium oxide), metal nitride particles (e.g., a chromium nitride), etc. In an embodiment where the pixel-defining film 118 includes a light-blocking material, external light reflection by metal structures arranged under the pixel-defining film 118 may be reduced.

A spacer 119 may be arranged on the pixel-defining film 118. The spacer 119 may be used to prevent damage to the substrate 100 in a manufacturing method for manufacturing a display device. A mask sheet may be used in manufacturing of the display panel 10, and in this case, when the mask sheet enters the opening 1180P of the pixel-defining film 118 or is in close contact with the pixel-defining film 118 to deposit a deposition material on the substrate 100, a defect in which a part of the substrate 100 is damaged or broken by the mask sheet may be prevented.

The spacer 119 may include an organic insulating material such as polyimide. Alternatively, the spacer 119 may include an inorganic insulating material such as silicon nitride or silicon oxide, or may include an organic insulating material and an inorganic insulating material.

In an embodiment, the spacer 119 may include a material that is different from that of the pixel-defining film 118. In another embodiment, the spacer 119 may include a same material as the pixel-defining film 118, and in such an embodiment, the pixel-defining film 118 and the spacer 119 may be formed together in a mask process using a halftone mask or the like.

An intermediate layer 212 may be arranged on the pixel-defining film 118. The intermediate layer 212 may include a light-emitting layer 212b arranged in the opening 1180P of the pixel-defining film 118.

The light-emitting layer 212b may include a polymer or low-molecular organic material that emits light of a selected color. A first functional layer 212a and a second functional layer 212c may be arranged below and above the light-emitting layer 212b, respectively. The first functional layer 212a may include, for example, a hole transport layer (HTL) or both an HTL and a hole injection layer (HIL). The second functional layer 212c is a component positioned on the light-emitting layer 212b and may be optional. The second functional layer 212c may include an electron transport layer (ETL) and/or an electron injection layer (EIL). The first functional layer 212a and/or the second functional layer 212c may be a common layer formed to cover the entire substrate 100 like a counter electrode 213 described below.

The counter electrode 213 may include a conductive material with a low work function. In an embodiment, for example, the counter electrode 213 may include a (semi)transparent layer including silver (Ag), magnesium (Mg), aluminum (Al), platinum PT, palladium (Pd), gold (Au), nickel (Ni), neodymium (Nd), iridium (Ir), chromium (Cr), lithium (Li), calcium (Ca), or an alloy thereof. The counter electrode 213 may further include a layer such as ITO, IZO, ZnO or In₂O₃ on the (semi)transparent layer including the aforementioned material. In some embodiments, a capping layer (not shown) may be further arranged on the counter electrode 213. The capping layer may include LiF, an inorganic material, and/or an organic material.

The encapsulation layer 300 may be arranged on the counter electrode 213. In an embodiment, the encapsulation layer 300 may include at least one inorganic encapsulation layer and at least one organic encapsulation layer, and FIG. 3 shows an embodiment where the encapsulation layer 300 includes a first inorganic encapsulation layer 310, an organic encapsulation layer 320, and a second inorganic encapsulation layer 330 that are sequentially stacked.

The first inorganic encapsulation layer 310 and the second inorganic encapsulation layer 330 may include at least one inorganic material selected from an aluminum oxide, a titanium oxide, a tantalum oxide, a hafnium oxide, a zinc oxide, a silicon oxide, a silicon nitride, and a silicon oxynitride. The organic encapsulation layer 320 may include a polymer-based material. The polymer-based material may include an acrylic resin, an epoxy resin, polyimide, polyethylene, or the like.

In an embodiment, the organic encapsulation layer 320 may include acrylate. Although not shown, a touch sensor layer may be arranged on the encapsulation layer 300. The touch sensor layer may obtain coordinate information based on an external input, e.g., a touch event. An optical functional layer (not shown) may be arranged on the touch sensor layer, although not shown in the drawing.

The optical functional layer may reduce the reflectivity of light (external light) incident from the outside toward the display device and/or improve the color purity of light emitted from the display device. In an embodiment, the optical functional layer may include a phase retarder and/or a polarizer. The phase retarder may be of a film type or liquid crystal coating type, and may include a λ/2 phase retarder and/or a λ/4 phase retarder.

The polarizer may be a film type or liquid crystal coating type. The film type may include a stretchable synthetic resin film, and the liquid crystal coating type may include liquid crystals arranged in a predetermined array. The phase retarder and the polarizer may further include a protective film.

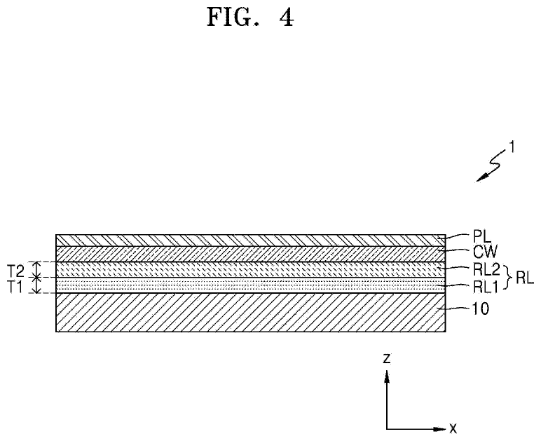

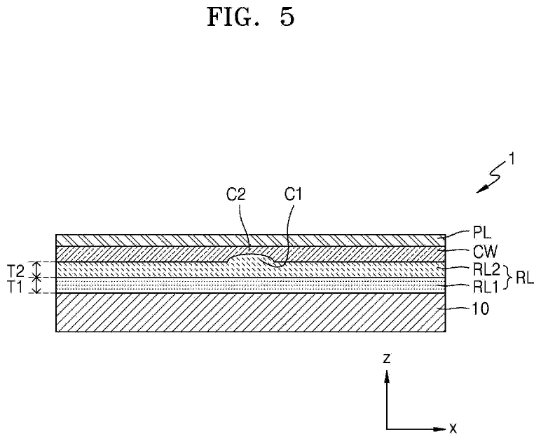

FIG. 4 is a cross-sectional view schematically showing a stacked structure of a display device according to an embodiment of the disclosure, and FIG. 5 is a cross-sectional view schematically showing a stacked structure of a display device according to another embodiment of the disclosure.

An embodiment of the display device 1 may include the display panel 10, a resin layer RL, and the cover window CW.

In an embodiment, the display panel 10 may include the display element DE arranged thereon. The display element DE may be an organic light-emitting diode (OLED). The display panel 10 may include the folding area FA in which the folding axis FAX is defined and the non-folding area NFA adjacent to the folding area FA.

The resin layer RL may be arranged on the display panel 10.

The resin layer RL may mean or be defined by a layer including a resin composition existing between the display panel 10 and the cover window CW.

Conventionally, a thickness of the display device 1 increases because of existence of a damping layer for reducing an impact between the display panel 10 and the cover window CW and a pressure sensitive adhesive (PSA) for adhering the display panel 10, the damping layer, and the cover window CW. The display device 1 according to an embodiment of the disclosure may minimize or substantially reduce the thickness of the display device 1 by including the resin layer RL effectively functioning as a conventional damping layer and the PSA between the display panel 10 and the cover window CW.

In an embodiment, the resin layer RL may include a first resin layer RL1 and a second resin layer RL2.

The first resin layer RL1 and the second resin layer RL2 may be classified based on positions thereof. The first resin layer RL1 may be arranged adjacent to the display panel 10, and the second resin layer RL2 may be arranged adjacent to the cover window CW.

That is, the display device 1 may have a stacked structure of the display panel 10, the first resin layer RL1, the second resin layer RL2, and the cover window CW. The first resin layer RL1 may be formed by applying a resin composition capable of forming the first resin layer RL1 to the display panel 10 and then curing the resin composition. The second resin layer RL2 may be formed by applying a resin composition capable of forming the second resin layer RL2 to the first resin layer RL1 and then curing the resin composition. The curing of the first resin layer RL1 and/or the curing of the second resin layer RL2 may be cured by heat or light.

The display device 1 may have a stacked structure of the display panel 10, the resin layer RL, and the cover window CW, and the display panel 10 may not have sufficiently or desirably high folding characteristics as the resin layer RL is usually thicker than the cover window CW, and high adhesive strength is desired as the display panel 10 and the cover window CW are bonded to each other through the resin layer RL.

In an embodiment, the display device 1 includes the first resin layer RL1 having a high elastic modulus, such that a neutral plane of the display device 1 may be directed downward toward the display panel 10 in folding of the display device 1 and a crack of the display panel 10 may be effectively prevented, thereby securing sufficiently or desirably high impact resistance characteristics and a high adhesion. Sufficiently or desirably high folding characteristics of the display device 1 may be secured by including the second resin layer RL2 having a low elastic modulus.

The first resin layer RL1 and the second resin layer RL2 may be classified based on the elastic moduli thereof.

In an embodiment, the first elastic modulus of the first resin layer RL1 may be greater than the second elastic modulus of the second resin layer RL2.

The first elastic modulus may be a storage modulus of the first resin layer RL1.

An upper limit of the first elastic modulus may be about 1000 megapascals (MPa), about 900 MPa, about 800 MPa, about 700 MPa, about 600 MPa, about 500 MPa, about 400 MPa, about 300 MPa, or about 200 MPa, and a lower limit thereof may be about 10 MPa, about 20 MPa, about 30 MPa, about 40 MPa, about 50 MPa, about 60 MPa, about 70 MPa, about 80 MPa, about 90 MPa, about 100 MPa, about 110 MPa, about 120 MPa, about 130 MPa, about 140 MPa, about 150 MPa, about 160 MPa, about 170 MPa, about 180 MPa, about 190 MPa, or about 200 MPa. The first elastic modulus may be within a range that is less than or equal to any of the upper limits described above and/or within a range that is greater than or equal to any of the lower limits described above.

Due to the first resin layer RL1 exhibiting the first elastic modulus in the numerical range described above, an adhesion between the first resin layer RL1 and the display panel 10 may be sufficiently or desirably high, and sufficiently or desirably high mechanical properties with improved impact resistance of the display device 1 may be exhibited. In case that the first elastic modulus is less than about 10 MPa, the mechanical properties of the display device 1 may not be sufficiently high in terms of impact resistance, and in case that the first elastic modulus exceeds about 1000 MPa, the adhesion between the first resin layer RL1 and the display panel 10 may not be sufficiently high. The impact resistance characteristic may mean characteristics in which the display device 1 may withstand the impact without causing a defect in case that an impact is applied from a direction of an outer protective layer PL of the display device 1.

In an embodiment, the second elastic modulus may be a tensile modulus of the second resin layer RL2.

The upper limit of the second elastic modulus may be about 0.1 MPa, about 0.09 MPa, about 0.08 MPa, about 0.07 MPa, about 0.06 MPa, or about 0.05 MPa, and the lower limit of the second elastic modulus may be about 0.01 MPa, about 0.02 MPa, about 0.03 MPa, about 0.04 MPa, or about 0.05 MPa. The second elastic modulus may be within a range that is less than or equal to any of the upper limits described above and/or within a range that is greater than or equal to any of the lower limits described above.

The display device 1 may exhibit sufficiently or desirably high folding characteristics due to the second resin layer RL2 exhibiting the second elastic modulus in the numerical range described above. In case that the second elastic modulus is less than about 0.01 MPa, the second resin layer RL2 may not be effectively manufactured, and in case that the second elastic modulus exceeds about 0.1 MPa, the folding characteristics of the display device 1 may not be sufficiently high.

The folding characteristics may indicate poor folding characteristics in case that a crack occurs in the folding area FA of the display device 1 or peeling occurs in stacked structure when the display device 1 is folded once or several times, and indicate sufficiently or desirably high folding characteristics in case that no crack occurs in the folding area FA and no peeling occurs in the stacked structure.

An upper limit of a yield strain of the second resin layer RL2 may be about 2.5%, about 2.4%, about 2.3%, about 2.2%, about 2.1%, or about 2.0%. The yield strain of the second resin layer RL2 may be within a range that is less than or equal to any of the upper limits described above. In case that the yield strain of the second resin layer RL2 is about 2.5% or less, sufficiently or desirably high bendability may be secured in folding of the display device 1.

In an embodiment, the first resin layer RL1 and/or the second resin layer RL2 may include at least one selected from an acrylate-based resin, a urethane-based resin, and a silicone-based resin. Herein, ‘-based resin’ means a resin containing a corresponding functional group.

In an embodiment, for example, the acrylic-based resin may include at least one selected from urethane acrylate and epoxy acrylate.

The urethane-based resin may include polyol, isocyanate, and a chain extender. The polyol may include at least one selected from polyether, polyester, polycarbonate, polybutadiene, and acryl. The isocyanate may include at least one selected from methylene diphenyl diisocyanate (MDI), hexamethylene diisocyanate (HDI), isophorone diisocyanate (IPDI), and 1,4-cyclohexane diisocyanate (CDI). The chain extender may include at least one selected from a diol, a diamine, a triol, a tetraiol, and an aminoalcohol.

In an embodiment where the first resin layer RL1 and/or the second resin layer RL2 includes a urethane-based polymer, the first elastic modulus and/or the second elastic modulus may be adjusted by rates of polyol, isocyanate, and the chain extender.

The silicone-based resin may be polymethylsiloxane (polydimethylsiloxane), which may include a linear polymer. In an embodiment where the first resin layer RL1 and/or the second resin layer RL2 includes the silicone-based resin, the first elastic modulus and/or the second elastic modulus may be adjusted depending on the degree of entanglement of the molecular structure of the linear polymer.

In an embodiment, a ratio of a thickness T2 of the second resin layer RL2 to a thickness T1 of the first resin layer RL1 may be in a range from about 0.5:1 to about 1:1, but is not limited thereto.

For example, in an embodiment where the thickness of the entire resin layer RL is about 150 micrometers (μm), the thickness T2 of the second resin layer RL2 may be in a range from about 50 μm to about 70 μm, and the thickness T1 of the first resin layer RL1 may be in a range from about 80 μm to about 100 μm.

In case that a ratio of the thickness T2 of the second resin layer RL2 to the thickness T1 of the first resin layer RL1 falls within the numerical range described above, both the folding characteristics and impact resistance characteristics of the display device 1 may be desirable or sufficiently high. In case that the thickness T2 of the second resin layer RL2 is less than a half of the thickness T1 of the first resin layer RL1, the folding characteristics of the display device 1 may not be sufficiently high, and in case that the thickness T2 of the second resin layer RL2 exceeds one time the thickness of the first resin layer RL1, the impact resistance characteristics of the display device 1 may not be sufficiently high.

The upper limit of the elastic modulus of the entire resin layer RL may be about 100 MPa, about 90 MPa, about 80 MPa or about 70 MPa, and the lower limit thereof may be about 40 MPa, about 50 MPa, about 60 MPa or about 70 MPa. The elastic modulus of the entire resin layer RL may be within a range that is less than or equal to any of the upper limits described above and/or within a range that is greater than or equal to any of the lower limits described above.

The elastic modulus of the entire resin layer RL may be a tensile modulus for the resin layer RL including both the first resin layer RL1 and the second resin layer RL2.

In case that the elastic modulus of the entire resin layer RL is in a range from about 40 MPa to about 100 MPa, both the folding characteristics and impact resistance characteristics of the display device 1 may be sufficiently or desirably high. In case that the elastic modulus of the entire resin layer RL is less than about 40 MPa, the impact resistance characteristics of the display device 1 may not be sufficiently high, and in case that the elastic modulus of the entire resin layer RL exceeds about 100 MPa, the folding characteristics of the display device 1 may not be sufficiently high.

An upper limit of a viscoelastic strain (creep) of the entire resin layer RL may be about 20%, about 19%, about 18%, about 17%, about 16%, or about 15%, and a lower limit thereof may be about 10%, about 11%, about 12%, about 13%, about 14%, or about 15%. The viscoelastic strain (creep) of the entire resin layer RL may be within a range that is less than or equal to any of the upper limits described above and/or within a range that is greater than or equal to any of the lower limits described above.

In case that the viscoelastic strain (creep) of the entire resin layer RL is not greater than about 20%, crease defect may not occur in the folding area FA, such that the folding characteristics of the display device 1 may be sufficiently or desirably high. In case that the viscoelastic strain (creep) of the entire resin layer RL exceeds about 20%, crease defects occur in the folding area FA, resulting in poor folding characteristics of the display device 1.

An upper limit of a recovery rate of the entire resin layer RL may be about 100%, about 99.9%, about 99.8%, about 99.7%, about 99.6%, about 99.5%, about 99.4%, about 99.3%, about 99.2%, about 99.1%, or about 99.0%, and a lower limit thereof may be about 90%, about 91%, about 92%, about 93%, about 94%, about 95%, about 96%, or about 99%. The recovery rate of the entire resin layer RL may be within a range that is less than or equal to any of the upper limits described above and/or within a range that is greater than or equal to any of the lower limits described above.

In case that the recovery rate of the entire resin layer RL is at least about 90%, crease defect may not occur in the folding area FA, such that the folding characteristics of the display device 1 may be sufficiently or desirably high. In case that the recovery rate of the entire resin layer RL is less than about 90%, crease defects occur in the folding area FA, resulting in poor folding characteristics of the display device 1.

An upper limit of the adhesion of the resin layer RL may be about 10000 g·f, about 9000 g·f, about 8000 g·f, about 7000 g·f, about 6000 g·f, or about 5000 g·f, and a lower limit thereof may be about 1000 g·f, about 1200 g·f, about 1300 g·f, about 1400 g·f, about 1500 g·f, about 1600 g·f, about 1700 g·f, about 1800 g·f, about 1900 g·f, or about 2000 g f. The adhesion of the entire resin layer RL may be within a range that is less than or equal to any of the upper limits described above and/or within a range that is greater than or equal to any of the lower limits described above.

As the cover window CW and the display panel 10 are directly bonded through the resin layer RL, sufficiently high adhesion is desired. In case that the adhesion of the resin layer RL is at least about 1000 g·f, bonding between the display panel 10 and the cover window CW is sufficiently or desirably high, such that even in spite of folding of the display device 1 several times, the display panel 10 and the cover window CW may not peel off.

In an embodiment, as shown in FIG. 5, the resin layer RL may include a convex portion C1 that is convex toward the cover window CW, and the cover window CW may include a concave portion C2 into which the resin layer RL is recessed, in which the convex portion C1 and the concave portion C2 may overlap each other and may overlap the folding area FA.

The resin layer RL may include the convex portion C1 that is convex toward the cover window CW, and the convex portion C1 may include the concave portion C2 into which the resin layer RL is recessed, in which the cover window CW may be made thin as the convex portion C1 and the concave portion C2 overlap each other. In case that the thickness of the cover window CW decreases due to the overlapping of the convex portion C1 and the concave portion C2, the neutral plane moves upward from the display panel 10 toward the cover window CW in folding of the display device 1, thereby weakening the adhesion between the display panel 10 and the cover window CW.

Accordingly, the display device 1 according to an embodiment of the disclosure may include a double resin layer including the first resin layer RL1 and the second resin layer RL2. The first resin layer RL1 with a high elastic modulus adjacent to the display panel 10 may secure sufficiently or desirably high impact resistance characteristics and a high adhesion by inducing the neutral plane to be directed downwardly toward the display panel 10 in folding of the display device 1 and effectively preventing cracks in the display panel 10, and the second resin layer RL2 with a low elastic modulus may secure sufficiently or desirably high folding characteristics of the display device 1.

The cover window CW may be arranged on the resin layer RL.

The cover window CW may be placed on the display panel 10, and in case that the touch sensor layer and/or the optical functional layer may be arranged, the cover window CW may be arranged on top thereof. The cover window CW may have a high transmissivity to transmit light emitted from the display panel 10. The cover window CW may also have strong strength and hardness to protect the display device 1 from external impact. In an embodiment, the cover window CW may be a flexible window. The cover window CW may protect the display panel 10 by being easily bent by external force without causing cracks, etc., therein. The cover window CW may include at least one selected from glass, sapphire, and plastic. The cover window CW may be, for example, ultra-thin tempered glass (ultra-thin glass) or colorless polyimide. In an embodiment, the cover window CW may have a structure in which a flexible polymer layer is arranged on one surface of a glass substrate, or may include a polymer layer. The cover window CW is not limited to a single layer. The cover window CW may include two or more films coupled or stacked together by an adhesive.

In an embodiment, the display device 1 may further include the outer protective layer PL.

The outer protective layer PL may be arranged on the cover window CW.

The outer protective layer PL may cover the entire top surface of the cover window CW. The outer protective layer PL may absorb external impact and effectively prevent scratches on the cover window CW from occurring. The outer protective layer PL may include, for example, a polymer resin such as polyimide or polyethylene, etc., or a urethane-based material.

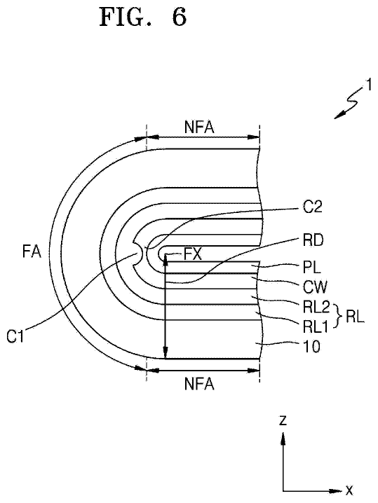

FIG. 6 is a cross-sectional view showing the stacked structure of the display device of FIG. 5 in a folded state.

Referring to FIG. 6, an embodiment of the display device 1 may include a stacked structure of the display panel 10, the resin layer RL, the cover window CW, and the outer protective layer PL, and the display device 1 may be folded with respect to the folding axis FAX defined by the folding area FA. The folding of the display device 1 may be performed in the direction (the z direction) in which the convex portion C1 faces the cover window CW.

An upper limit of a radius of curvature RD of the display panel 10 in folding with respect to the folding axis FAX defined by the folding area FA may be about 100 mm, about 90 mm, about 80 mm, about 70 mm, about 60 mm, about 50 mm, about 40 mm, about 30 mm, about 20 mm, or about 10 mm, and a lower limit thereof may be about 1 mm, about 2 mm, about 3 mm, about 4 mm, about 5 mm, about 6 mm, about 7 mm, about 8 mm, about 9 mm, or about 10 mm. The radius of curvature RD of the display panel 10 may be within a range that is less than or equal to any of the upper limits described above and/or within a range that is greater than or equal to any of the lower limits described above.

The radius of curvature RD may mean a distance from the folding axis FAX defined by the folding area FA to the top of the display device 1 when the display device 1 is folded.

In the display device 1 according to an embodiment of the disclosure, the display panel 10 has folding reliability for a radius of curvature RD of about 1 millimeter (mm) or greater around the folding axis FAX, thus having sufficiently or desirably high folding characteristics. As the display device 1 according to an embodiment of the disclosure includes not only the first resin layer RL1 but also the second resin layer RL2, the display device 1 may have the low radius of curvature RD, and thus may have improved folding reliability and folding characteristics even at the low radius of curvature RD. The second resin layer RL2 may be controlled to exhibit a lower elastic modulus than the first resin layer RL1, such that a composite structure of the display device 1 according to an embodiment of the disclosure may have improved folding reliability and folding characteristics despite the low radius of curvature RD.

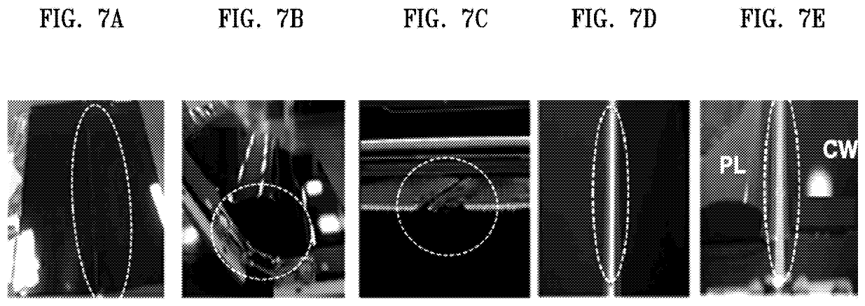

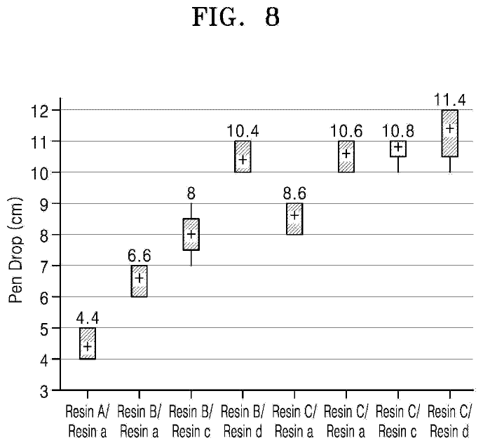

FIGS. 7A to 7E are photographs showing folding characteristics of a comparative example of the disclosure, and FIG. 8 is a graph showing measured impact resistance characteristics of an embodiment and a comparative example of the disclosure.

Through experiment with various combinations of resin layers RL, results such as those shown in [Table 1], [Table 2], and [Table 3] below may be obtained.

[Table 1] shows physical properties of components of the first resin layer RL1 and the second resin layer RL2, and [Table 2] shows physical properties of the display device 1 including the first resin layer RL1 and the second resin layer RL2. Resin A, Resin B, and Resin C are polymers included in the second resin layer RL2, Resin a, Resin b, Resin c, and Resin d are polymers included in the first resin layer RL1, and Resin A, Resin B, Resin C, Resin a, Resin b, Resin c, and Resin d may include acrylate-based resins.

In [Table 1], εγ may mean a yield strain, Cycle may mean a recovery rate, Creep may mean a viscoelastic strain, and Adhesion may mean an adhesion. The moduli of Resin A, Resin B, and Resin C may refer to storage moduli and may be measured with a rheometer. The moduli of Resin a, Resin b, Resin c, and Resin d may refer to the tensile moduli, and may be measured using a universal testing machine (UTM) or a flexible testing machine (FTM).

In [Table 2], the composite structure may mean a composite structure manufactured by stacking the first resin layer RL1 and the second resin layer RL2. εγ may mean a yield strain, Recovery may mean a recovery rate, Creep may mean a viscoelastic strain, and Adhesion may mean an adhesion. The modulus of the composite structure may refer to the tensile modulus. The yield strain may be a strain when permanent deformation occurs, the recovery rate may be a recovery rate after 100 folding and unfolding cycles, and the viscoelastic strain may refer to a strain when creep deformation occurs for 1 hour, and may be measured with a UTM or a FTM.

[Table 3] shows the results of evaluating the folding characteristics and impact resistance of the display device 1 of the comparative example and the embodiment. The folding characteristics may be indicated as NG in case that the display device 1 is defective in folding, and as OK in case that the display device 1 is normal. The impact resistance characteristics (Pen drop) may be a measurement of the height at which a defect occurs in the display device 1 when a Pen with a diameter of 0.3Φ (pi) is dropped toward the outer protective layer PL of the display device 1 in which the Pen drop is performed 10 times and the average value of the height at which a defect occurs in the display device 1 is expressed by discarding a decimal part and only showing an integer part.

TABLE 1

| | Single layer | | | | | | |
|---|---|---|---|---|---|---|---|
| Characteristics | Resin A | Resin B | Resin C | Resin a | Resin b | Resin c | Resin d |
| Modulus (MPa) | 0.1 | 0.06 | 0.04 | 50 | 100 | 1.9 | 230 |
| εγ (%) | 1.9 | 2.1 | 2.1 | 2 | 2.2 | 1.9 | 2 |
| Recovery (%) | 93 | 95 | 90 | 85 | 92 | 90 | 95 |
| Creep (%) | 2 | 2 | 0 | 80 | 43 | 30 | 22 |
| Adhesion (g · f) | 500 | 700 | 800 | 1200 | 1000 | 1500 | 1800 |

TABLE 2

| | Composite structure | | | | | | | |
|---|---|---|---|---|---|---|---|---|
| | Resin A/ | Resin B/ | Resin B/ | Resin B/ | Resin C/ | Resin C/ | Resin C/ | Resin C/ |
| Characteristics | Resin a | Resin a | Resin c | Resin c | Resin a | Resin b | Resin c | Resin d |
| Modulus (MPa) | 38 | 43 | 130 | 205 | 40 | 82 | 116 | 200 |
| εγ (%) | 2 | 2 | 1.9 | 2.1 | 2.1 | 2 | 1.9 | 2.2 |
| Recovery (%) | 87 | 91 | 90 | 92 | 92 | 93 | 91 | 93 |
| Creep (%) | 25 | 20 | 22 | 19 | 18 | 15 | 11 | 10 |
| Adhesion (g · f) | 1100 | 1100 | 1400 | 1600 | 1200 | 1100 | 1500 | 1700 |

TABLE 3

| | | Folding | impact resistance | |
|---|---|---|---|---|
| | | characteristics | (Pen drop) | |
| Single | Resin A | OK | 3 | cm |
| layer | Resin B | OK | 3 | cm |
| | Resin C | OK | 2 | cm |
| | Resin a | NG | 7 | cm |
| | Resin b | NG | 9 | cm |
| | Resin c | NG | 12 | cm |
| | Resin d | NG | 14 | cm |
| Composite | Resin A/ | NG | 4 | cm |
| structure | Resin a | | | |
| | Resin B/ | OK | 6 | cm |
| | Resin a | | | |
| | Resin B/ | NG | 8 | cm |
| | Resin c | | | |
| | Resin B/ | NG | 10 | cm |
| | Resin d | | | |
| | Resin C/ | OK | 8 | cm |
| | Resin a | | | |
| | Resin C/ | OK | 10 | cm |
| | Resin b | | | |
| | Resin C/ | NG | 10 | cm |
| | Resin c | | | |
| | Resin C/ | NG | 11 | cm |
| | Resin d | | | |

Referring to FIGS. 7A to 7E, it may be seen that in case that the folding characteristics of the display device 1 correspond to NG during folding, a crack may occur in the cover window CW (refer to FIGS. 7A and 7C), a wrinkle defect may occur in the cover window CW (refer to FIG. 7D), and the cover window CW and the display panel 10 may be peeled off (refer to FIG. 7B).

Referring to FIG. 8, it may be seen that a single layer (Resin a, Resin b, Resin c, and Resin d) and a composite structure (Resin A/Resin a, Resin B/Resin c, Resin B/Resin d, Resin C/Resin c, and Resin C/Resin d) do not have sufficiently or desirably high folding characteristics, such that a crack may occur in the cover window CW during folding, a wrinkle defect may occur in the cover window CW, and the cover window CW and the display panel 10 may be peeled off.

It may also be seen that the single layer (Resin a, Resin b, Resin c, and Resin d) and the composite structure (Resin B/Resin a, Resin B/Resin c, Resin C/Resin a, Resin C/Resin b, Resin C/Resin c, and Resin C/Resin d) have sufficiently or desirably high impact resistance properties, with a height at which a defect of the display device 1 occurs being about 6 cm or greater during a pen drop test.

Therefore, it may be seen that the composite structures (Resin B/Resin a, Resin C/Resin a, and Resin C/Resin b) exhibit both sufficiently or desirably high folding properties and sufficiently or desirably high impact resistance properties. As the moduli of the composite structures (Resin B/Resin a, Resin C/Resin a, and Resin C/Resin b) are about 40 MPa to about 100 MPa, it may be seen that in case that a modulus of a composite structure of the first resin layer PL1 and the second resin layer PL2 is in a range from about 40 MPa to about 100 MPa, both the folding characteristics and the impact resistance characteristics of the display device 1 are sufficiently or desirably high.

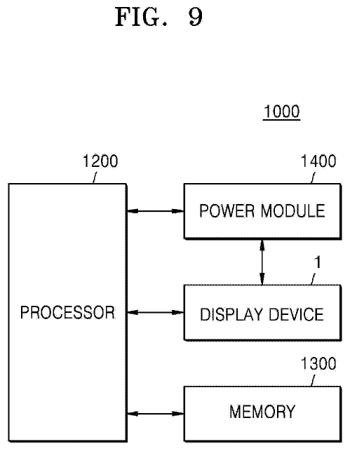

FIG. 9 is a block diagram of an electronic device including a display device according to an embodiment of the disclosure.

Referring to FIG. 9, an electronic device 1000 manufactured using a display panel manufacturing device according to an embodiment of the disclosure may include a display device 1, a processor 1200, a memory 1300, and a power module 1400.

The display device 1 may receive data from the processor 1200 and provide visual information. The display device 1 may be the display device 1 according to the embodiments of the disclosure described above.

The processor 1200 may include at least one selected from a central processing unit (CPU), an application processor AP, a graphic processing unit (GPU), a communication processor (CP), an image signal processor (ISP), and a controller. In an embodiment, for example, the processor 1200 may operate by executing at least one program.

The memory 1300 may store data information used for the operation of the processor 1200 or the display device 1. In an embodiment, for example, the memory 1300 may store at least one program. In case that the processor 1200 executes an application stored in the memory 1300, an image data signal and/or an input control signal may be transmitted to the display device 1, and the display device 1 may process the received signal and output the image information through a display screen.

The power module 1400 may include a power supply module, such as a power adapter, a battery device, etc., and a power conversion module that converts power supplied by the power supply module to generate power used for the operation of the electronic device 1000. In an embodiment, for example, the power module 1400 may supply power to the display device 1.

At least one of the components of the electronic device 1000 may be included in the display device 1 according to the above-described embodiments. Some of individual modules functionally included in a module may be included in the display device 1 and others may be provided separately from the display device 1.

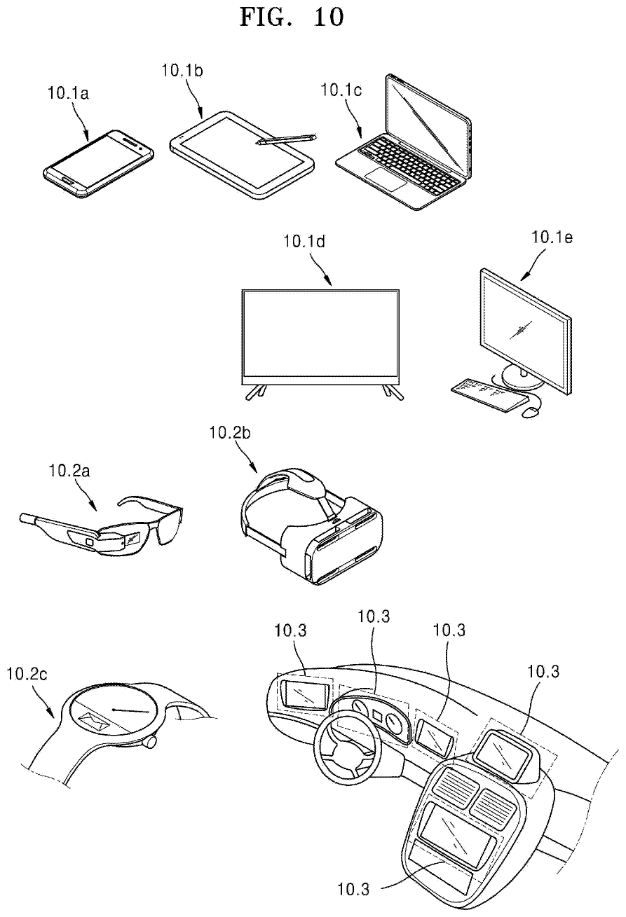

FIG. 10 schematically shows an electronic device including a display device according to various embodiments of the disclosure.

Referring to FIG. 10, various electronic devices including the display device 1 according to the disclosure may include not only image display electronic devices such as a smart phone 10.1a, a tablet personal computer (PC) 10.1b, a laptop computer 10.1c, a television (TV) 10.1d, a desk monitor 10.1e, etc., but also wearable electronic devices including display devices such as smart glasses 10.2a, a head mounted display 10.2b, a smart watch 10.2c, etc., and vehicle electronic devices 10.3 including display modules such as an instrument panel, a center fascia, a center information display (CID) arranged on a dashboard, a room mirror display, etc., of vehicles.

Herein, a display device including a protective member according to an embodiment of the disclosure is specifically described with reference to an embodiment and a comparative example. In addition, the embodiment shown below may be an example to help understanding of the disclosure, and the scope of the disclosure is not limited thereto.

Each of the embodiments described above may be implemented independently, but it goes without saying that a structure of each embodiment may also be applied in combination to other embodiments.

Specific implementations described in the embodiments are examples and do not limit the scope of the embodiments in any way. In addition, when there is no specific mentioning, such as “essential” or “important”, it may not be a necessary component for the application of the disclosure.

In the specification (especially, claims) of the disclosure, the use of the term “the” and similar indicators thereof may correspond to both the singular and the plural. In addition, in case that the range is described in the embodiments, the range includes the disclosure to which an individual value falling within the range is applied (unless stated otherwise), and is the same as the description of an individual value constituting the range in the description of the disclosure. Finally, in case that there is no apparent description of the order of operations constituting the method according to the disclosure or a contrary description thereof, the operations may be performed in an appropriate order. The disclosure is not necessarily limited according to the describing order of the operations. The use of all examples or exemplary terms in the disclosure are to simply describe the disclosure in detail, and unless the range of the disclosure is not limited by the examples or the exemplary terms unless limited by the claims. It may be understood by those of ordinary skill in the art that various modifications, combinations, and changes may be made according to design conditions and factors within the scope of the appended claims or equivalents thereof.

Embodiments of the disclosure provide a display device capable of maintaining reliability even after folding or bending and an electronic device including the display device.

Embodiments of the disclosure also provide a display device having sufficiently or desirably high impact resistance and an electronic device including the display device.

The invention should not be construed as being limited to the embodiments set forth herein. Rather, these embodiments are provided so that this disclosure will be thorough and complete and will fully convey the concept of the invention to those skilled in the art.

The invention should not be construed as being limited to the embodiments set forth herein. Rather, these embodiments are provided so that this disclosure will be thorough and complete and will fully convey the concept of the invention to those skilled in the art.

What is claimed is:

1. A display device comprising:
a display panel, in which a display element is arranged, wherein the display panel comprises a folding area along which a folding axis is defined, and a non-folding area adjacent to the folding area;
a resin layer arranged on the display panel; and
a cover window arranged on the resin layer,
wherein the cover window comprises glass,
the resin layer comprises a convex portion which is convex toward the cover window, the cover window comprises a concave portion corresponding to the convex portion of the resin layer, and the convex portion and the concave portion overlap each other,
the resin layer comprises a first resin layer arranged adjacent to the display panel and a second resin layer arranged adjacent to the cover window, and
a first elastic modulus of the first resin layer is greater than a second elastic modulus of the second resin layer.

2. The display device of claim 1, wherein an elastic modulus of the resin layer is in a range from about 40 MPa to about 100 MPa.

3. The display device of claim 1, wherein an adhesion of the resin layer is about 1000 g·f or greater.

4. The display device of claim 1, wherein the first elastic modulus is in a range from about 10 MPa to about 1000 MPa.

5. The display device of claim 4, wherein an elastic modulus of the resin layer is in a range from about 40 MPa to about 100 MPa.

6. The display device of claim 4, wherein a ratio of a thickness of the second resin layer to a thickness of the first resin layer is in a range from about 0.5:1 to about 1:1.

7. The display device of claim 1, wherein the second elastic modulus is in a range from about 0.01 MPa to about 0.1 MPa.

8. The display device of claim 7, wherein an elastic modulus of the resin layer is in a range from about 40 MPa to about 100 MPa.

9. The display device of claim 7, wherein a ratio of a thickness of the second resin layer to a thickness of the first resin layer is in a range from in a range from about 0.5:1 to about 1:1.

10. The display device of claim 1, wherein a ratio of a thickness of the second resin layer to a thickness of the first resin layer is in a range from about 0.5:1 to about 1:1.

11. An electronic device comprising:
a processor which generates a scan input signal;
a power module which generates a scan input voltage; and
a display device which processes the scan input signal and displays an image, wherein the display device comprises:
a display panel, in which a display element is arranged, wherein the display panel comprises a folding area along which a folding axis is defined, and a non-folding area adjacent to the folding area;
a resin layer arranged on the display panel; and
a cover window arranged on the resin layer,
wherein the cover window comprises glass,
the resin layer comprises a convex portion which is convex toward the cover window, the cover window comprises a concave portion corresponding to the convex portion of the resin layer, and the convex portion and the concave portion overlap each other,
the resin layer comprises a first resin layer arranged adjacent to the display panel and a second resin layer arranged adjacent to the cover window, and
a first elastic modulus of the first resin layer is greater than a second elastic modulus of the second resin layer.

12. The electronic device of claim 11, wherein an elastic modulus of the resin layer is in a range from about 40 MPa to about 100 MPa.

13. The electronic device of claim 11, wherein an adhesion of the resin layer is about 1000 g·f or greater.

14. The electronic device of claim 11, wherein the first elastic modulus is in a range from about 10 MPa to about 1000 MPa.

15. The electronic device of claim 14, wherein an elastic modulus of the resin layer is in a range from about 40 MPa to about 100 MPa.

16. The electronic device of claim 14, wherein a ratio of a thickness of the second resin layer to a thickness of the first resin layer is in a range from 0.5:1 to 1:1.

17. The electronic device of claim 11, wherein the second elastic modulus is in a range from about 0.01 MPa to about 0.1 MPa.

18. The electronic device of claim 17, wherein an elastic modulus of the resin layer is in a range from about 40 MPa to about 100 MPa.

19. The electronic device of claim 17, wherein a ratio of a thickness of the second resin layer to a thickness of the first resin layer is in a range from about 0.5:1 to about 1:1.

20. The electronic device of claim 11, wherein a ratio of a thickness of the second resin layer to a thickness of the first resin layer is in a range from about 0.5:1 to about 1:1.
